(19) United States
(12) Patent Application Publication
(10) Pub. No.: US 2008/0211499 A1
(43) Pub. Date: Sep. 4, 2008

(54) Low Power Decoupling for Multi-Nuclear Spectroscopy

(75) Inventors: David L. Foxall, Mentor, OH (US); James B. Murdoch, Solon, OH (US); Larry Kasuboski, Solon, OH (US)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N. V., Eindhoven (NL)

(21) Appl. No.: 11/917,684

(22) PCT Filed: Jun. 13, 2006
(86) PCT No.: PCT/IB2006/051886

§ 371 Date: Dec. 14, 2007

Related U.S. Application Data
(60) Provisional application No. 60/691,114, filed on Jun. 16, 2005.

(51) Int. Cl. G01R 33/46

(52) U.S. Cl. 324/311; 702/189

(57) ABSTRACT

In a magnetic resonance spectroscopy method, first nuclear species magnetic resonance is excited. A spin echo of the first nuclear species magnetic resonance is generated, and the spin echo is read out. The first and second nuclear species are decoupled during the generating of the spin echo but not during the reading. At least the generating, the reading, and the decoupling are repeated for a plurality of different decoupling times to generate heteronuclear J-modulated data.

The following relates to the magnetic resonance arts. It finds particular application in multi-nuclear magnetic resonance spectroscopy observing ¹³C or ¹⁵N nuclei bonded to ¹H nuclei, and to imaging or other data analysis employing data collected by such spectroscopy, and will be described with particular reference thereto. However, it finds application more generally in multi-nuclear magnetic resonance spectroscopy observing substantially any nuclear species bonded to another hetero-nuclear species, and to chemical shift imaging or other data analysis employing data collected by such spectroscopy.

Magnetic resonance spectroscopy can provide information on the chemical bonding of the imaged nuclear species, through observation of chemical shifts caused by the chemical environment. For example, when observing the ¹³C nuclear species, chemical shift information can distinguish the C, CH, CH₂, and CH₃ chemical configurations. Such chemical information can be used for various applications, such as tracking the metabolism of an injected tracer.

A complication arises due to scalar coupling, also called J-coupling, between the nuclei. For example, J-coupling causes the resonance line from a CH₂ or other chemically bonded configuration to split in frequency space to form a multiplet. The presence of spin coupling therefore reduces the signal-to-noise ratio, and the overlap of multiplets from different chemically shifted resonances obscures the spectrum.

Secondary radio frequency irradiation is applied at the magnetic resonance frequency of the coupled second nuclear species during readout of the observed magnetic resonance to remove the effects of scalar coupling (J-coupling) between the nuclei in order to simplify the spectrum and increase the signal-to-noise ratio. The process is referred to simply as “decoupling”. For example, ¹³C nuclei are commonly bonded with ¹H and show strong couplings with J˜100-200 Hz. When observing ¹³C, the J-coupling with hydrogen can be suppressed by applying secondary radio frequency irradiation at the ¹H magnetic resonance frequency during the readout phase of the magnetic resonance spectroscopy sequence, so that only a single line is observed for each chemically bonded configuration.

The use of decoupling in performing magnetic resonance spectroscopy of ¹³C, ¹⁵N, and other nuclear species of interest has led to its widespread application and has generated many methods that optimize its bandwidth, efficiency, and power for collapsing couplings across the full width of the proton spectrum. However, the existing techniques have certain disadvantages. The suppressed J-coupling information is inherently lost, and the applied secondary radio frequency irradiation substantially increases the specific absorption rate (SAR) of the magnetic resonance spectroscopy sequence.

Increased SAR is highly disadvantageous in medical applications where the observed subject is a human patient. Increased SAR is also of particular concern in high-field magnetic resonance scanners, such as 3T scanners and the more recently developed 7T scanners, where the increased central magnetic field requires the use of increased radio frequency power levels to produce the same degree of nuclear excitation.

The secondary radio frequency irradiation used for decoupling should be sufficiently broadband to span the frequency range of the chemical shift spectrum of the coupled species. For example, to decouple protons over a chemical shift range of 6.5 ppm, the secondary radio frequency irradiation should encompass a decoupling bandwidth of 830 Hz at 3T (128 MHz ¹H magnetic resonance frequency), and should encompass a decoupling bandwidth of 1936 Hz at 7T (298 MHz ¹H magnetic resonance frequency). Thus, a relatively broadband secondary radio frequency irradiation is called for, which is applied throughout the readout phase in order to suppress J-coupling effects. The relatively broadband nature and extended time over which the secondary radio frequency irradiation is applied leads to substantially heightened SAR.

The present invention contemplates improved apparatuses and methods that overcome the aforementioned limitations and others.

According to one aspect, a magnetic resonance spectroscopy method is disclosed. A first nuclear species magnetic resonance is excited, the excitation encompassing either the whole volume of the subject, or a smaller volume of interest restricted by the application of selective radio frequency pulses and magnetic field gradients. A spin echo signal from the first nuclear species magnetic resonance is generated, and is either read out directly, or encoded spatially with additional magnetic field gradient pulses. The first nuclear species and a second coupled hetero-nuclear species are decoupled using a pulse applied on a secondary radio frequency channel during the generation of the spin echo. Decoupling to suppress hetero-nuclear J-coupling is not applied during the signal read out. At least the spin echo generation, the reading, and the radio frequency pulse applied on the secondary radio frequency channel are repeated for a plurality of different spin evolution times (Δ) to spectrally encode data with a modulation due to hetero-nuclear J-coupling.

According to another aspect, a magnetic resonance apparatus is disclosed, including a magnetic resonance scanner, and a controller controlling the magnetic resonance scanner to perform the magnetic resonance spectroscopy method set forth in the preceding paragraph.

According to another aspect, a magnetic resonance apparatus is disclosed. A means is provided for acquiring heteronuclear J-modulated data. A processor processes the acquired heteronuclear J-modulated data to extract at least one of (i) coupling information, (ii) chemical shift information, or (iii) spatial information when this is separately encoded with magnetic field gradients.

According to another aspect, a magnetic resonance spectroscopy method is disclosed. A first nuclear species magnetic resonance is excited, the excitation encompassing either the whole volume of the subject, or a smaller volume of interest restricted by the application of selective radio frequency pulses and magnetic field gradients. A spin echo signal from the first nuclear species magnetic resonance is generated, and the spin echo is either read out directly, or encoded spatially with additional magnetic field gradient pulses. During the generation of the spin echo, J-coupling of the first nuclear species with a second coupled hetero-nuclear species is spectrally encoded by the application of broadband decoupling to the second nuclear species over the spin evolution interval (Δ). Decoupling to suppress hetero-nuclear J-coupling is not applied during the signal read out. Signal acquisition with spectral encoding is repeated using a plurality of different decoupling time intervals (Δ) to generate hetero-nuclear J-modulated data containing both chemical shift and J-coupling information. The hetero-nuclear J-modulated data are processed to extract at least one of the chemical shift information, the J-coupling information, or spatial information when this is separately encoded with magnetic field gradients.

One advantage resides in reduced SAR in multi-nuclear magnetic resonance spectroscopy with suppressed J-coupling.

Another advantage resides in acquiring multi-nuclear magnetic resonance spectroscopy including separated chemical shift and J-coupling information.

Another advantage resides in suppression of J-coupling with concomitant retention of high signal-to-noise ratio in one-dimensional chemical shift spectra acquired by multi-nuclear magnetic resonance spectroscopy.

Numerous additional advantages and benefits will become apparent to those of ordinary skill in the art upon reading the following detailed description of the preferred embodiments.

The invention may take form in various components and arrangements of components, and in various process operations and arrangements of process operations. The drawings are only for the purpose of illustrating preferred embodiments and are not to be construed as limiting the invention.

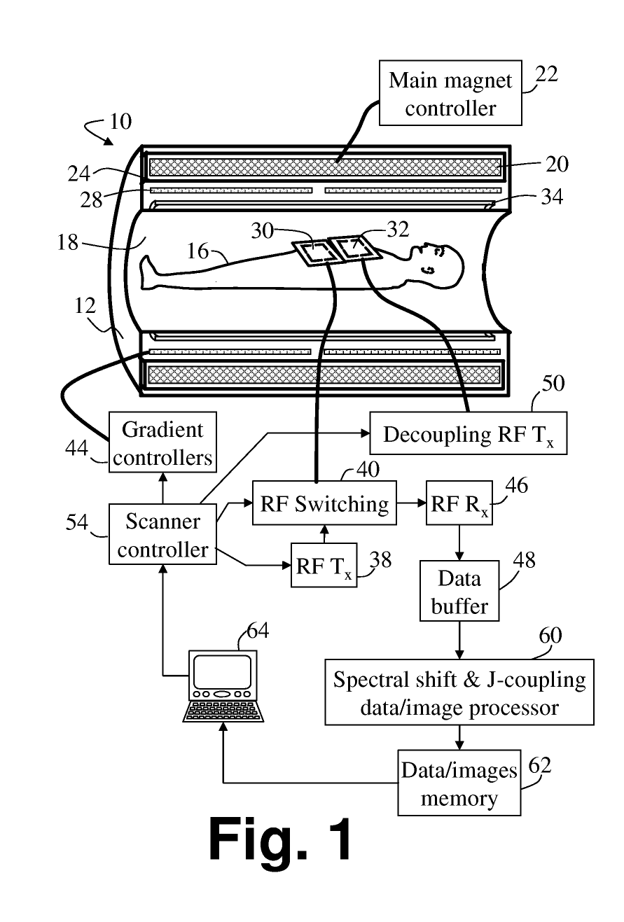

FIG. 1 diagrammatically shows a magnetic resonance system for performing multi-nuclear magnetic resonance spectroscopy, including the capability of acquiring separated chemical shift and J-coupling information, and the capability of performing spectroscopy-based imaging or other data analysis.

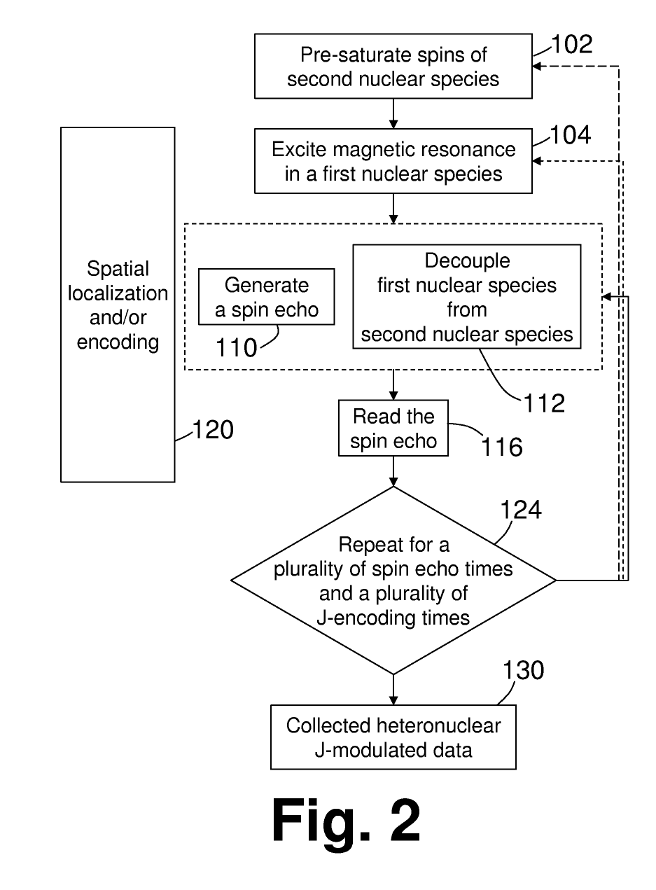

FIG. 2 diagrammatically shows a multi-nuclear magnetic resonance spectroscopy acquisition method, including optional spatial localization and/or spatial encoding, suitably performed by the system of FIG. 1.

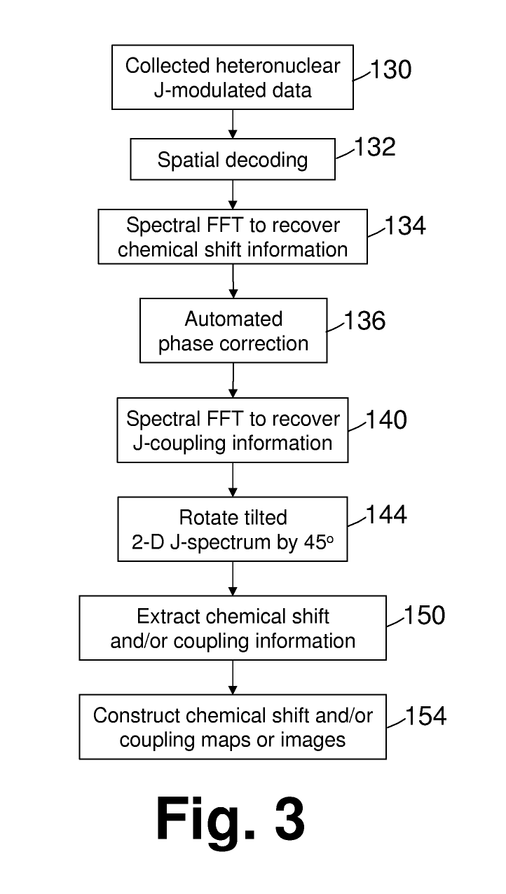

FIG. 3 diagrammatically shows a data processing and optional image reconstruction method suitably performed by the data/imaging processor of the system of FIG. 1.

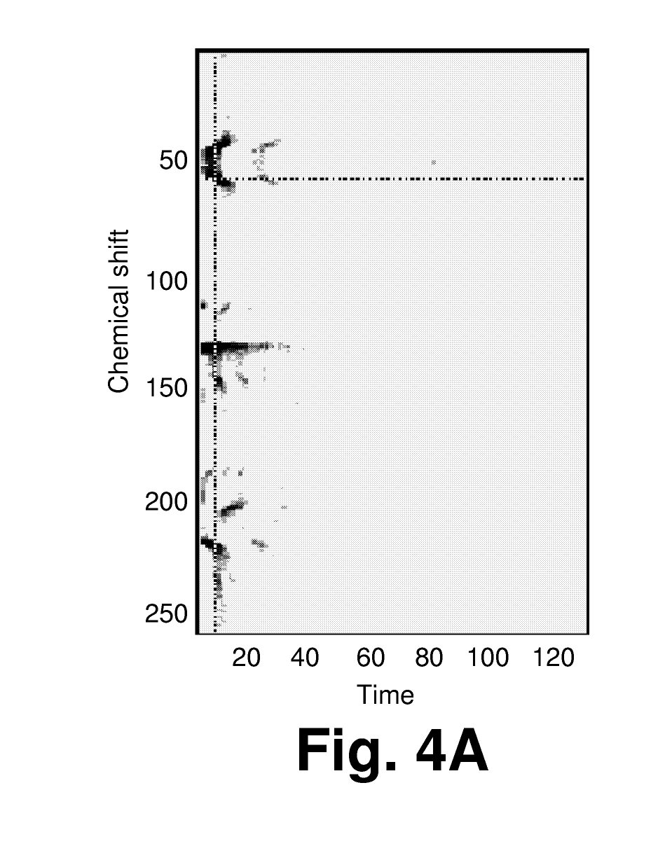

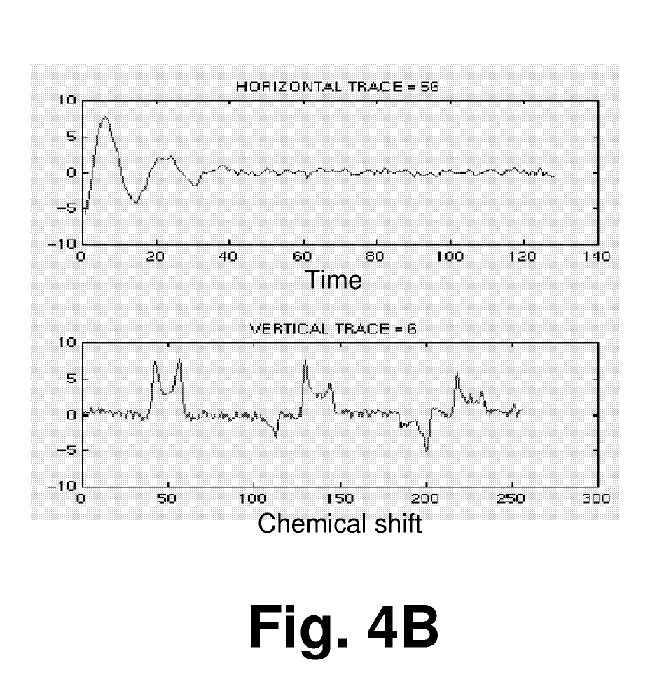

FIG. 4A shows an example two-dimensional data matrix after a spectral fast Fourier transform performed to recover chemical shift information. FIG. 4B shows horizontal and vertical traces along the horizontal and vertical lines, respectively, indicated in FIG. 4A.

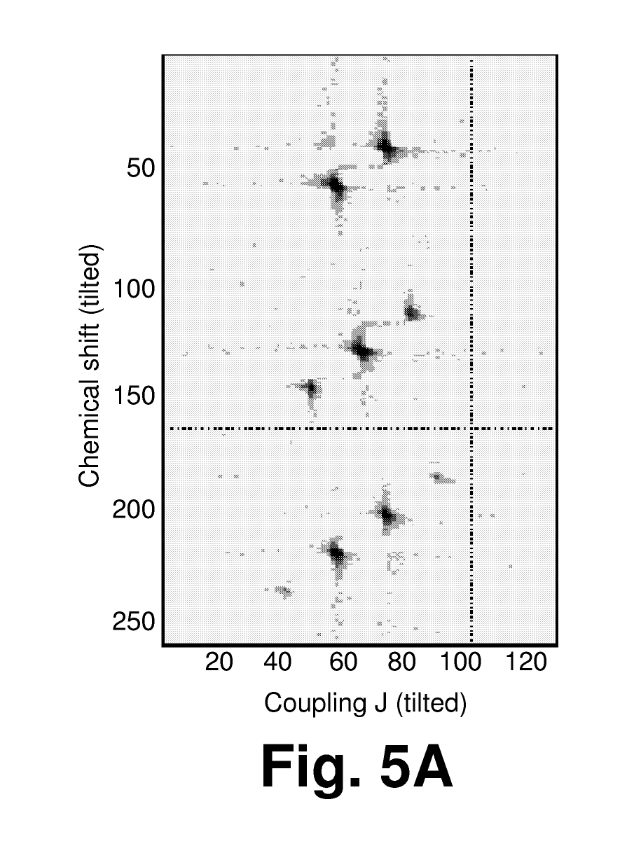

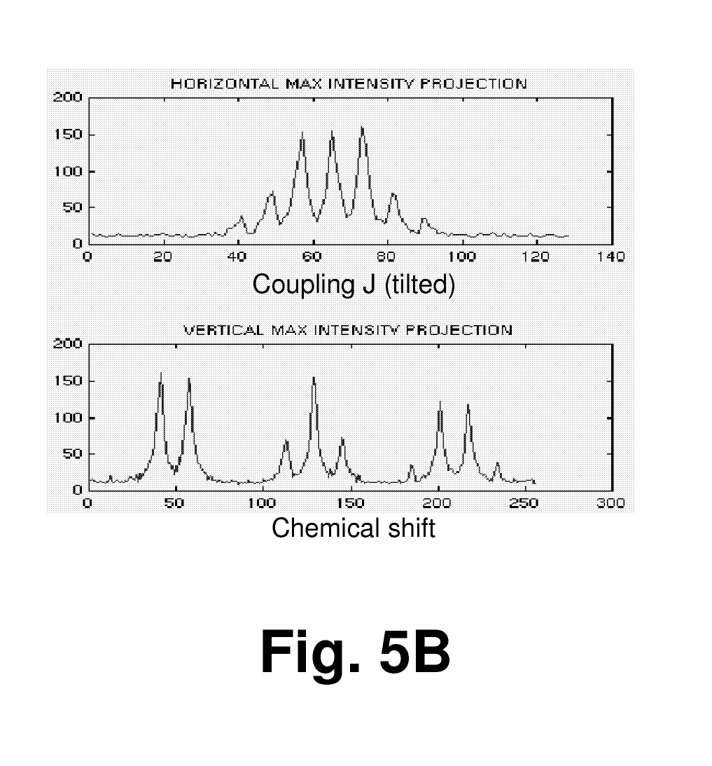

FIG. 5A shows an example tilted two-dimensional J-spectrum having tilted axes corresponding to chemical shift and J-coupling components, obtained by a second spectral fast Fourier transform performed to recover the J-coupling information. FIG. 5B shows horizontal and vertical maximum intensity projections (MIP's) of the tilted two-dimensional J-spectrum of FIG. 5A.

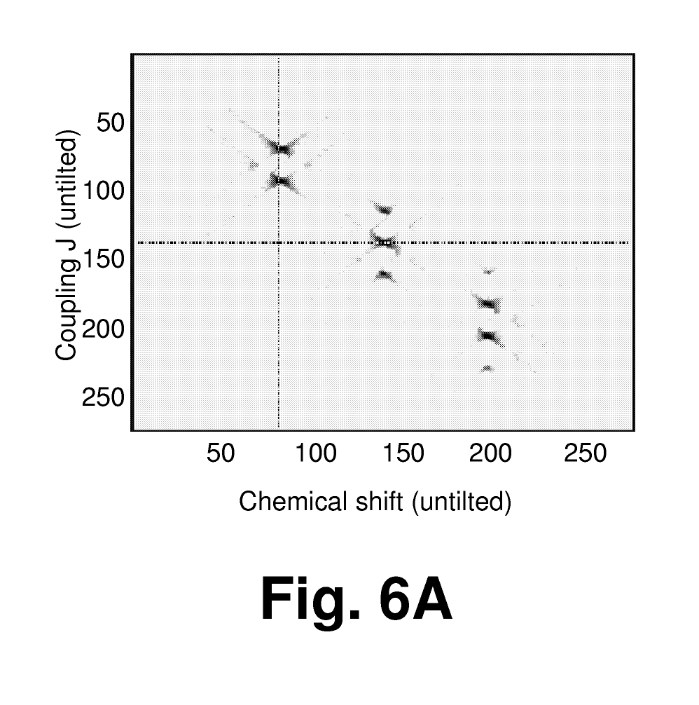

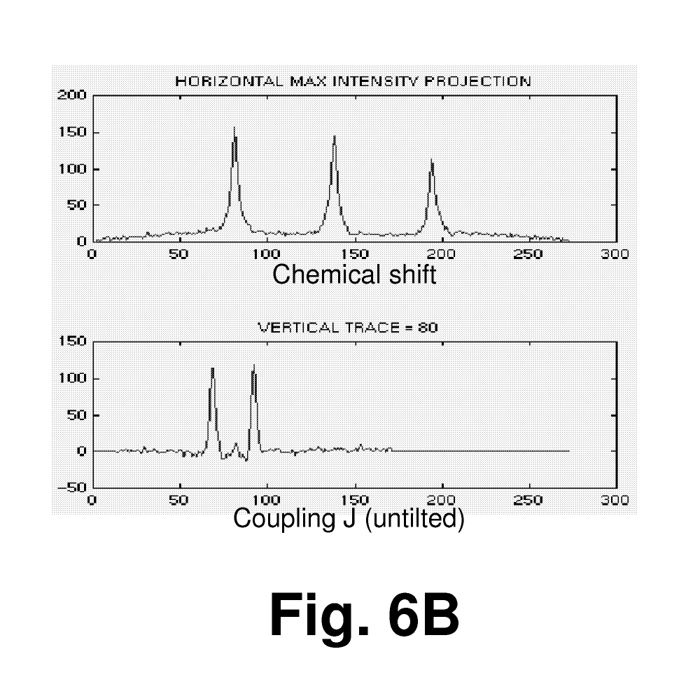

FIG. 6A shows an example untilted two-dimensional J-spectrum having horizontal and vertical axes corresponding to chemical shift and J-coupling, respectively, obtained by a 45° rotation of the tilted two-dimensional J-spectrum of FIG. 5A.

FIG. 6B shows a horizontal maximum intensity projections (MIP) of the two-dimensional J-spectrum of FIG. 6A and a vertical trace along the vertical line indicated in FIG. 6A.

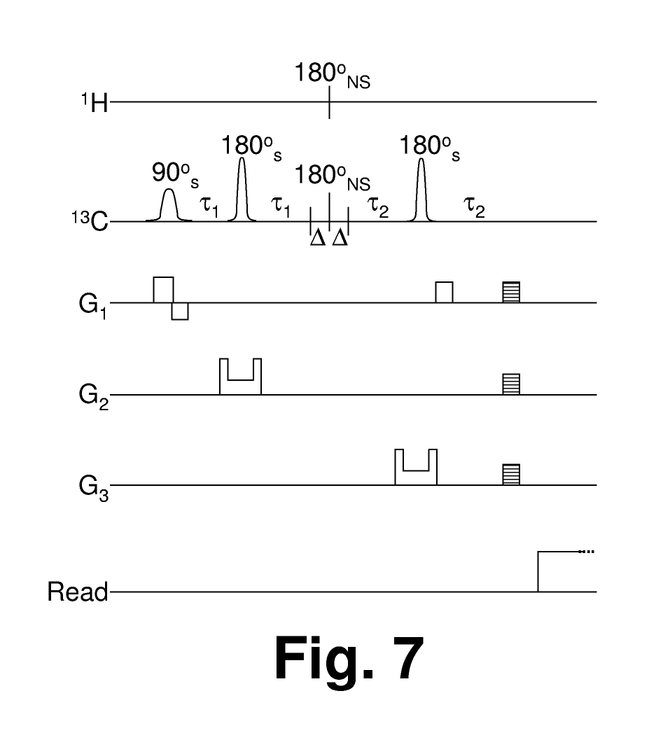

FIG. 7 diagrammatically shows an example multi-nuclear magnetic resonance spectroscopy pulse sequence for observing the ¹³C nuclear species including determination of both J-coupling and chemical shift of the ¹³C caused by bonded ¹H nuclei. The multi-nuclear magnetic resonance spectroscopy pulse sequence of FIG. 7 includes applied magnetic field gradients for providing spatial localization and spatial encoding. Hetero-nuclear J modulation is introduced by the use of a radio frequency pulse applied at the ¹H resonance frequency.

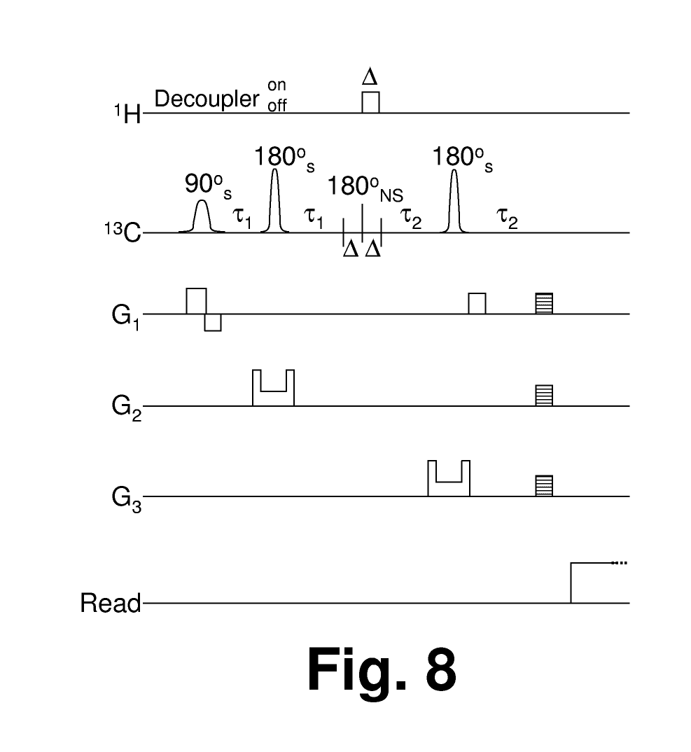

FIG. 8 diagrammatically shows another example multi-nuclear magnetic resonance spectroscopy pulse sequence for observing the ¹³C nuclear species including determination of both J-coupling and chemical shift of the ¹³C caused by bonded ¹H nuclei. The multi-nuclear magnetic resonance spectroscopy pulse sequence of FIG. 8 includes applied magnetic field gradients for providing spatial localization and spatial encoding. Hetero-nuclear J modulation is introduced by the use of gated broadband decoupling applied at the ¹H resonance frequency.

With reference to FIG. 1, a magnetic resonance scanner 10 includes a scanner housing 12 in which a patient 16 or other observed subject is at least partially disposed. A protective insulating bore liner 18 of the scanner housing 12 optionally lines a cylindrical bore or opening of the scanner housing 12 inside of which the observed subject 16 is disposed. A main magnet 20 disposed in the scanner housing 12 is controlled by a main magnet controller 22 to generate a main (B₀) magnetic field in at least an observed region of the observed subject 16. Typically, the main magnet 20 is a persistent superconducting magnet surrounded by cryoshrouding 24. In some embodiments, the main magnet 20 generates a main magnetic field of about 3 Tesla or higher. In some embodiments, the main magnet 20 generates a main magnetic field of about 7 Tesla or higher.

Magnetic field gradient coils 28 are arranged in or on the housing 12 to superimpose selected magnetic field gradients on the main magnetic field in at least the observed region of the observed subject 16. Typically, the magnetic field gradient coils include coils for producing three orthogonal magnetic field gradients, such as x-gradients, y-gradients, and z-gradients. At least two radio frequency coils 30, 32 (or alternatively a single coil capable of being tuned to at least two different radio frequencies) are disposed in the bore of the scanner 10.

One or more of the radio frequency coils, namely the local coil 30 in FIG. 1, is used to inject radio frequency excitation pulses at a magnetic resonance frequency of the observed nuclear species and to measure the excited magnetic resonance signals. Optionally, different coils are used for excitation and reading; for example, a whole-body radio frequency coil 34 mounted in the scanner 10 can be used for magnetic resonance excitation at the magnetic resonance frequency of the observed nuclear species, while the local coil 30 can be used for reading the excited magnetic resonance.

Additionally, one or more of the radio frequency coils, namely the local coil 32 in FIG. 1, is used to apply a secondary radio frequency irradiation at the magnetic resonance frequency of a second hetero-nuclear species that is J-coupled to the observed nuclear species. The applied secondary radio frequency irradiation is used to selectively invert the spin state of the second nuclear species or broadband decouple it from the first nuclear species at one or more selected time intervals before the readout of the excited magnetic resonance of the first nuclear species.

In this Detailed Description, the example of ¹³C is used as the observed nuclear species, and the example of ¹H is used as the chemically bonded second nuclear species. However, it is to be appreciated that either or both of the observed first nuclear species and the chemically bonded second nuclear species can be other species. For example, the observed first nuclear species can be ¹⁵N and the bonded second nuclear species can be ¹H. For hetero-nuclear spectroscopy, the first nuclear species and the second nuclear species typically have different atomic number (Z) values. For example, carbon has Z=6 while hydrogen has Z=1.

During magnetic resonance spectroscopy data acquisition, a radio frequency power source 38 operating at the magnetic resonance frequency of the observed first nuclear species (e.g., ¹³C) is coupled to the local coil 30 through radio frequency switching circuitry 40 to inject radio frequency excitation pulses at the magnetic resonance frequency of the observed first nuclear species into the observed region of the observed subject 16 so as to excite magnetic resonance in spins of the first nuclear species (e.g., ¹³C). Optionally, a magnetic field gradients controller 44 operates the magnetic field gradient coils 28 to spatially localize the magnetic resonance excitation to a slab or other localized region. The radio frequency power source 38 further operates the local coil 30 to generate one or more spin echoes, for example by applying one or more inversion pulses at the magnetic resonance frequency to invert the excited magnetic resonance of the first nuclear species so as to generate one or more spin echoes. Optionally, the magnetic field gradient controller 44 operates the magnetic field gradient coils 28 to apply one or more spatial encoding magnetic field gradient pulses. During the magnetic resonance readout phase of the pulse sequence, the switching circuitry 40 disconnects the radio frequency transmitter 38 from the local coil 30, and connects a radio frequency receiver 46 to the local coil 30 to acquire magnetic resonance data from the observed region of the observed subject 16. The acquired magnetic resonance data are stored in a data buffer 48.

A second, decoupling radio frequency transmitter 50 operates the local coil 32 at a magnetic resonance frequency of the second nuclear species (e.g., ¹H) during the generating of the spin echo, but not during the reading out of the spin echo, so as to decouple the first and second nuclear species to generate heteronuclear J-modulation. Under the control of a scanner controller 54, low power adiabatic radio frequency pulses are applied at the magnetic resonance frequency of the second nuclear species (e.g., ¹H) to invert the spin states of the decoupled nucleus simultaneously with a spin-refocusing pulse at the magnetic resonance frequency of the first nuclear species (e.g., ¹³C) to generate a spin echo, and using a variable time delay (A) to encode spin evolution under the influence of heteronuclear J-coupling. The variable time delay is incremented by an amount sufficient to sample a spectral bandwidth in the J-coupling dimension larger than the widest multiplet expected to be encountered. For the example of ¹³C observe nuclei and ¹H coupled nuclei, a —CH₃ group will generate a quartet with a width of 3J Hz; accordingly, increment times of less than or equal to ⅙ J are suitable.

A sufficient number of transients are collected, with the transients distributed over the whole (chemical shift and J-coupling) data acquisition, to yield the desired signal to noise ratio in a final one-dimensional chemical shift spectrum. For example, if 128 transients correspond to a desirable ¹³C signal-to-noise ratio, then collecting sixteen time increments with eight averages, or thirty-two time increments with four averages each, is suitable. The signal-to-noise ratio of the final decoupled one-dimensional spectrum obtained from the data matrix is proportional to the square root of the total number of transients used to acquire the data matrix, so the distribution of transients and encodings can be assigned fairly flexibly.

A spectral shift and J-coupling data/image processor 60 performs data and optional image processing, such as: processing the collected magnetic resonance data with a series of complex one-dimensional spectral fast Fourier transform operations for each encoded data line to recover chemical shift and J-coupling data; performing optional image reconstruction using one or more spatial fast Fourier transform operations; phase correcting the data to remove both zero order and first order phase errors; transposing the data array and reconstructing the J-spectrum domain of the nuclear magnetic resonance (NMR) data set with a complex ID FFT operation for each data line; rotating the data matrix through an angle selected to align the elements of each coupled multiplet transverse to the chemical shift axis; projecting a decoupled spectrum onto the chemical shift axis; scaling the decoupled spectrum to correct a chemical shift scale while allowing for the angle of rotation used to make the projection; applying spectral peak detection to the decoupled spectrum to classify the resonances; extracting traces or projecting regions from the rotated data matrix to reveal coupling patterns that lie parallel to the J-spectrum axis; peak detecting along the J-spectrum axis to determine the multiplicity of the coupling pattern; assigning the decoupled spectral lines to suitable chemical configurations such as —C, —CH, —CH₂, —CH₃ or —N, —NH, —NH₂, —NH₃ groupings, or so forth. The resulting processed data or images are suitably stored in a data/images memory 62, displayed on a user interface 64, printed, communicated over the Internet or a local area network, stored on a non-volatile storage medium, or otherwise used. In the embodiment illustrated in FIG. 1, the user interface 64 also interfaces a radiologist or other operator with the scanner controller 54 to control the magnetic resonance scanner 10. In other embodiments, a separate scanner control interface may be provided.

FIG. 2 diagrammatically shows an example multi-nuclear magnetic resonance spectroscopy acquisition sequence 100 suitably executed by the scanner controller 54. In an operation 102, an optional pre-saturating of the proton spins of the second nuclear species (e.g., ¹H) is performed, using for example a low power half passage adiabatic pulse generated by the local coil 32 and decoupling radio frequency transmitter 50. The optional pre-saturating operation 102 provides nuclear Overhauser enhancement of the subsequently excited magnetic resonance of the observed first nuclear species (e.g., ¹³C).

The optional pre-saturation 102 is followed by an excitation operation 104 during which spins of the observed first nuclear species (e.g., ¹³C) are excited to produce magnetic resonance. The excitation can use a 90° or other flip-angle radio frequency pulse at the magnetic resonance frequency of the first nuclear species.

A spin echo generating operation 110 generates one or more spin echoes of the excited magnetic resonance of the first nuclear species. The spin echo can be generated, for example, by applying one or more 180° inversion pulses at the magnetic resonance frequency of the first nuclear species. A decoupling operation 112 is performed during a selected portion of the generating of the spin echo. The decoupling operation 112 applies one or more radio frequency pulses, optionally adiabatic pulses, at the resonance frequency of the second nuclear species (e.g., ¹H) so as to perturb the J-coupling between the first and second nuclear species for a selected time interval denoted herein as the spin evolution time interval A. In a readout operation 116, the generated spin echo is read out by the radio frequency receiver 46, and the read out data is stored in the data buffer 48. To limit SAR, the decoupling operation 112 does not extend into the readout 116.

Optionally, one or more spatial localization and/or encoding operations 120 are performed during one or more of the excitation 104, spin echo generating 110, readout 116, or during intervals therebetween. For example, spatial encoding magnetic field gradients can be applied between the spin echo generation and the readout to provide spatial phase encoding.

A repeat operation 124 repeats at least the spin echo generating 110, decoupling 112, and readout 116, for a number of transients. Depending upon the rate of decay of the magnetic resonance, the repeating 124 may also repeat the excitation 104 and optionally also the pre-saturating 102. The transients can include averaging repetitions of transients having the same spin evolution time interval A so as to increase the signal-to-noise ratio for the chemical shift spectrum. The transients also include transients with different spin evolution time intervals A to provide modulation data in the J-coupling dimension. The plurality of transients acquired by the repetitions 124 define collected heteronuclear J-modulated data 130.

With reference to FIG. 3, a suitable data processing and optional image processing method 150 is applied to the collected heteronuclear J-modulated data 130 by the data/images processor 60 of FIG. 1. If the acquisition method 100 of FIG. 2 included spatial encoding 120, then suitable spatial decoding operations 132 are applied to recover the spatial information. For example, if the spatial encoding 120 employed Cartesian phase encoding, then the spatial decoding operations 132 suitably include spatial FFT's in the phase-encoded directions. It will be appreciated that two, three, four and five dimensional variations of the method are possible depending on how many spatial directions are encoded.

With continuing reference to FIG. 3 and with further reference to FIG. 4A, a spectral fast Fourier transform (i.e., “spectral FFT”) 134 is applied to recover the chemical shift spectrum. FIG. 4A shows an example two-dimensional data matrix in a case where ¹³C is the observed first nuclear species and ¹H the coupled second nuclear species, produced by the spectral FFT 134 performed to recover chemical shift information. FIG. 4B shows horizontal and vertical traces along the horizontal and vertical lines, respectively, indicated in FIG. 4A. The vertical data lines represent J-modulated ¹³C spectra of CH (doublet), CH₂ (triplet), and CH₃ (quartet) functional groups or chemical configurations. Horizontal lines represent the interferrograms for the J-modulation.

With returning reference to FIG. 3, because the decoupling operation 112 does not extend into the readout 116, the collected transients encode a phase-twist line shape. Optionally, an automated phase correction 136 is applied to correct for the phase-twist line shape encoded in the collected transients. In one suitable approach, the phase correction is computed using a data line collected with the spin evolution time delay interval Δ=0. The Δ=0 transient is subjected to a one-dimensional fast Fourier transform to create complex spectral data. In some embodiments, both a zero order (frequency independent) phase correction and a first order (frequency dependent) phase correction are applied to separate the complex spectral data into the absorption mode and dispersion mode spectra. The absorption mode data and dispersion mode data are separately fast Fourier transformed to resolve the J-modulation into the J-spectrum. The real part of the absorption mode data and the imaginary part of the dispersion mode data can be combined to form a J-spectrum with pure absorption line shapes in both the chemical shift and J-coupling directions. The imaginary part of the absorption mode data and the real part of the dispersion mode data can either be discarded at this stage or combined to form a J-spectrum with pure dispersion mode line shapes. This processing removes the phase-twist line shape artifact and the unwanted line broadening introduced by the admixing of absorption and dispersion mode line shape contributions that occurs when a simple fast FFT is used to reconstruct the J-spectrum.

One suitable embodiment of the automated phase correction 136 employs a data line collected with Δ=0. The absolute value of the complex data line at Δ=0 is computed to produce a spectrum A(v) which is a suitable approximation to the absorption part |S(v)| of the correctly phased spectrum. That is, A(v)≅|S(v)|. From the absolute value spectrum |S(v)|, an approximation to the dispersion part of the correctly phased spectrum is computed using a Hilbert transform. Taken together the absolute value spectrum |S(v)| and its Hilbert transform H(v) form an approximation to the correctly phased spectrum Sₐ(v)=|S(v)|+iH(v). A function of the difference Sₐ(v)−exp(−i(Z+Fv))S(v) is minimized so that estimates of the both the zeroeth and first order phase correction parameters are obtained. The function used for the minimization can, for example, be a least squares criterion, a least first power, Chebyshev or other like criteria.

A variation of the automated phase correction procedure is to take the phase difference between the Hilbert approximation to the correctly phased spectrum and the actual spectrum, and use this phase difference to correct the other transients of the data matrix.

A second spectral FFT 140 employing a complex one-dimensional FFT operation for each data line is applied, after transposing the matrix, to the separated absorption mode data and dispersion mode data. The real and imaginary parts of the two data sets are then combined so as to reconstruct the two dimensional magnetic resonance data set (J-spectrum) in pure absorption mode. The recovered J-spectrum domain data is, however, tilted by 45° because decoupling was not applied during the readout 116.

FIG. 5A shows an example tilted two-dimensional J-spectrum in the case of ¹³C observed first nuclear species and coupled ¹H second nuclear species, produced by the spectral FFT 140. The tilted two-dimensional J-spectrum has tilted axes corresponding to chemical shift and J-coupling components. The matrix now holds the full heteronuclear two-dimensional J-spectrum. Coupling patterns for the CH (doublet), CH₂ (triplet), and CH₃ (quartet) chemical configurations are visible in projections taken in both directions.

FIG. 5B shows horizontal and vertical maximum intensity projections (MIP's) of the tilted two-dimensional J-spectrum of FIG. 5A. The vertical projection represents the coupled ¹³C spectrum. The horizontal projection shows a superposition of the coupling patterns for all chemical configurations.

As noted previously, the J-spectrum recovered by the second spectral FFT 140 is tilted by 45° because the decoupling was not applied during the readout 116. Accordingly, a rotation operation 144 rotates the J-spectrum by 45° to recover the untilted J-spectrum having horizontal and vertical axes corresponding to chemical shift and J-coupling, respectively.

In a variation of the procedure used to correctly align the chemical shift and J-coupling axes before projection and analysis, an affine transformation can be applied to the J-spectrum to skew the data matrix so that the two axes become orthogonal. This approach has the advantage that data matrices with an intrinsic difference in frequency resolution between the chemical shift and J-coupling axes may also be transformed for onward processing.

FIG. 6A shows an example untilted two-dimensional J-spectrum in the case of ¹³C observed first nuclear species and coupled ¹H second nuclear species, having horizontal and vertical axes corresponding to J-coupling and chemical shift, respectively. The untilted two-dimensional J-spectrum of FIG. 6A was obtained by applying the 45° rotation operation 144 to the tilted two-dimensional J-spectrum of FIG. 5A. The ¹³C multiplets are now aligned at right angles to the horizontal chemical shift axis. FIG. 6B shows a horizontal maximum intensity projections (MIP) of the two-dimensional J-spectrum of FIG. 6A and a vertical trace along the vertical line indicated in FIG. 306A. The horizontal projection yields a decoupled version of the ¹³C spectrum with three chemical configuration resonances (CH, CH₂, CH₃).

In a variation of the procedure the projection of the decoupled spectrum is obtained by summing the data lines of the untilted J-spectrum. This modification has the advantage of preserving the full signal-to-noise ratio of the acquired data.

With continuing reference to FIGS. 6A and 6B and with returning reference to FIG. 3, the untilted two-dimensional J-spectrum is suitably processed in a processing operation 150 to extract chemical shift and/or coupling information. For example, vertical traces taken through the matrix, such as the example vertical trace shown in FIG. 6B, show the coupling patterns for each chemical configuration that gives rise to a resonance in the spectrum allowing them to be assigned as doublet, triplet, and quartet multiplets by pattern recognition.

In some embodiments, the processing 150 includes automated multiplet type recognition employing pattern recognition on the untilted two-dimensional J-spectrum of FIG. 6A. Lines that contain multiplet patterns are first identified by performing a constrained peak fitting on the horizontal projection in which each chemical configuration is represented by a single line. Using the resulting line position information allows traces containing multiplet patterns due to hetero-nuclear coupling to be extracted from the J-spectrum. For ¹³C, there are four multiplet types: singlet, doublet, triplet, and quartet, having one, two, three, and four spectral lines, respectively, in the patterns. The J-coupling component lines of the patterns have 1; 1:1, 1:2:1, and 1:3:3:1 relative intensities. The heteronuclear coupling constants (that is, J values) for ¹³C lie within a relatively narrow range of about 125-200 Hz. Multiplets can therefore be characterized with a constrained peak fit using an overall amplitude parameter, a coupling constant (J) parameter, and a central frequency shift. Multiplet signal power and trace noise power can be estimated by performing an inverse FFT on the extracted trace to obtain a pseudo-echo signal. The signal power in the pseudo-echo can be estimated by summing the signal magnitude squared over the central half of the data set that contains the echo peak (S). The noise power in the pseudo-echo can be estimated by summing signal magnitude squared over the first and last quarters of data set (N). The signal-to-noise ratio (SNR) of the multiplet can be estimated according to:

$$S N R = \sqrt{\frac{S}{N}} . \qquad ( 1 )$$

The amplitudes for the different multiplet pattern possibilities in the spectral domain can also be estimated from the signal power of the pseudo-echo using Parseval's Theorem that states that the total signal power (noise and signal) is the same in the two domains. Shift and J coupling parameters can be estimated using the constrained spectral line fitting for each multiplet type on the trace. Triplets can be distinguished from quartets and doublets on the basis of the overall power in the least square residuals, since triplet patterns typically have a poor fit to either true doublets or true quartets. Doublets and quartets can be distinguished on the basis of the second moment of the least square residuals taken about the multiplet center. The outer lines of a true quartet contribute strongly to this measure when compared with a doublet template fitted to the inner two lines.

While the pattern recognition is advantageously applied to the untilted J-spectrum (such as the example untilted J-spectrum of FIG. 6A), it is also contemplated to perform pattern recognition at an earlier stage of the reconstruction. For example, pattern recognition can be applied to the tilted J-spectrum (such as the example tilted J-spectrum of FIG. 5A).

With continuing reference to FIG. 3, if the spatial encoding 120 is employed, then an imaging or mapping operation 154 can construct two-dimensional or three-dimensional coupling images or maps. For example, the data collection can be carried out in a two-dimensional slab selective mode and phase encoded with an additional variable gradient pulse to create sub-voxels within the slab. The spatial decoding 132 employs two spatial FFT's. The imaging or mapping operation 154 can provide a grayscale image or map of the intensity of a particular chemical configuration (C, CH, CH₂, CH₃) for the sampled sub-voxels of the slab. Additionally or alternatively, color-coding can be used to distinguish the various multiplets in a single image or map. The data collection can also be carried out in a three-dimensional volume-selective mode and phase encoded with two additional independently variable gradient pulses to create sub-voxels within the volume. The spatial decoding 132 in this case employs three spatial FFT's.

FIG. 7 diagrammatically illustrates one suitable pulse sequence for performing the data acquisition method 100 of FIG. 2, including providing for voxel-localized spectroscopy and chemical shift imaging if the optional variable spatial encoding gradients are supplied. In FIG. 7, radio frequency pulses at the observed first magnetic resonance frequency are plotted on a horizontal axis labeled “¹³C”, while radio frequency pulses at the decoupling second magnetic resonance frequency are plotted on a horizontal axis labeled “¹H”. Each radio frequency pulse is labeled by flip angle, and by a subscript indicating whether the radio frequency pulse is spatially selective (subscript “S”) or spatially non-selective (subscript “NS”). It is to be recognized that each pulse may be a single pulse, or a packet of pulses collectively providing the indicated flip angle. The spatially selective 90° pulse, in conjunction with the spatial localization provided by the first gradient pulse in the “G1” direction, provides the excitation 104 of a spatial slab. Two spatially selective 180° inversion pulses at the ¹³C resonance frequency surrounding a third spatially non-selective 180° pulse at the ¹³C resonance frequency provide the spin echo with spatial localization provided by the gradient pulses in the “G2” and “G3” directions. The directions “G1”, “G2”, and “G3” are typically mutually orthogonal to one another. The non-selective 180° pulse at the ¹H resonance frequency is applied concurrently with the middle, non-selective 180° pulse at the ¹³C resonance frequency to provide hetero-nuclear J-modulation over the spin evolution time intervals labeled Δ. The second gradient pulse in the “G1” direction is a spoiler pulse to suppress unwanted coherence. Variable amplitude gradient pulses in the “G1”, “G2”, and “G3” provide optional spatial encoding in up to three spatial dimensions.

FIG. 8 diagrammatically illustrates another suitable pulse sequence for performing the data acquisition method 100 of FIG. 2, including providing for voxel-localized spectroscopy. In FIG. 8, radio frequency pulses at the observed first magnetic resonance frequency are plotted on a horizontal axis labeled “¹³C”, while periods of decoupling activity at the second magnetic resonance frequency are plotted on a horizontal axis labeled “¹H Decoupler”. Each radio frequency pulse is labeled by flip angle, and by a subscript indicating whether the radio frequency pulse is spatially selective (subscript “S”) or spatially non-selective (subscript “NS”). It is to be recognized that each pulse may be a single pulse, or a packet of pulses collectively providing the indicated flip angle. The spatially selective 90° pulse, in conjunction with the spatial localization provided by the first gradient pulse in the “G1” direction, provides the excitation 104 of a spatial slab. Two spatially encoded 180° inversion pulses at the ¹³C resonance frequency surrounding a third spatially non-selective 180° pulse at the ¹³C resonance frequency provide the spin echo with spatial localization provided by the gradient pulses in the “G2” and “G3” directions. The directions “G1”, “G2”, and “G3” are typically mutually orthogonal to one another. Decoupling activity gated on for a time period Δ is used to provide hetero-nuclear J-modulation by removing the action of the J coupling effect asymmetrically in the spin echo pulse train applied to the observe nucleus. The decoupling transmitter may be gated on in either the first or second A evolution period, but not in both. The nature of the decoupling activity can optionally be a single frequency coherent pulse, a broadband frequency or phase modulated transmission, or a train of refocusing pulses that constantly inverts the spin state of the second coupled nucleus.

It is to be appreciated that the pulse sequences of FIGS. 7 and 8 are illustrative examples. The skilled artisan can readily construct other pulse sequences for performing data collection in accordance with the methods described herein. For example, in some other suitable pulse sequences, Hadamard encoding is employed along with a gated decouple spin echo. In Hadamard encoding, the slice selective inversion pulses are applied before the 90° pulse used to create the spin echo. These are rather like the inversion pulse used in inversion recovery spin echo imaging. The inversion pulses encode space by inverting magnetization along the Z axis. The signal from a particular voxel is reconstructed by adding and subtracting data acquired with different configurations of inversion pulses (spatial encoding is done by switching the RF inversion pulses on and off). A Hadamard Transform is used to reconstruct the Hadamard-encoded data. Sequences employing Hadamard encoding are advantageous for spatially encoding multi-nuclear spectroscopy acquisitions of nuclei which have long T1 values and short T2 values. The Hadamard selection sequence is suitably applied in front of a gated decouple spin echo.

In performing the decoupling, adiabatic radio frequency pulses, or pulse packets have the advantage of providing decoupling with low power and hence low SAR. For example, if protons are to be decoupled over a chemical shift range of 6.5 ppm (spanning a decoupling range of 830 Hz at 3T, or 1936 Hz at 7T), conventional pulsed decoupling calls for radio frequency field strengths of the same order as the chemical shift range. On the other hand, a low-power adiabatic pulse can invert the same proton range with a radio frequency field strength of only about 400-500 Hz. The J-modulation employed in the method of the first embodiment disclosed herein uses only inversion of the decoupled nucleus spin state and evolution of the transverse coherence during time interval 2Δ, or in the method of the second embodiment, the use of broadband decoupling during the first time interval Δ, followed by a period of evolution for the transverse coherence during the second time interval Δ. These procedures introduce substantially less SAR than does decoupling over the readout phase of the magnetic resonance sequence.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A magnetic resonance spectroscopy method comprising:
exciting first nuclear species magnetic resonance;
generating a spin echo of the first nuclear species magnetic resonance;
reading out the spin echo;
decoupling the first and a second coupled hetero-nuclear species during the generating of the spin echo but not during the reading; and
repeating at least the generating, the reading, and the decoupling for a plurality of different spin evolution times (A) to generate hetero-nuclear J-modulated data.

2. The method as set forth in claim 1, wherein the first nuclear species is ¹³C and the second nuclear species is ¹H.

3. The method as set forth in claim 1, wherein the first nuclear species and the second nuclear species have different atomic number (Z) values.

4. The method as set forth in claim 1, wherein:
the generating of the spin echo includes applying a radio frequency refocusing pulse at a first species resonance frequency to invert spins of the first nuclear species magnetic resonance; and
the decoupling includes applying a radio frequency pulse at a second species resonance frequency contemporaneously with the first species refocusing pulse.

5. The method as set forth in claim 1, wherein the decoupling includes:
applying saturating radio frequency power at a magnetic resonance frequency of the second nuclear species during at least a portion of the generating; and
not applying the saturating radio frequency power during the reading.

6. The method as set forth in claim 5, wherein the applying of saturating radio frequency power at the magnetic resonance frequency of the second nuclear species includes:
applying saturating radio frequency power at the magnetic resonance frequency of the second nuclear species with a bandwidth encompassing a chemical shift range corresponding to chemical bonding relationships between the first and second nuclear species.

7. The method as set forth in claim 1, wherein the decoupling includes:
applying an adiabatic radio frequency pulse or pulse packet at the magnetic resonance frequency of the second nuclear species encompassing at least a frequency range of chemical shifts corresponding to chemical bonding relationships between the first and second nuclear species.

8. The method as set forth in claim 1, wherein the decoupling includes:
applying a single radio frequency pulse packet during the generating of the spin echo.

9. The method as set forth in claim 1, further including:
processing the heteronuclear J-modulated data to extract at least one of (i) coupling information and (ii) chemical shift information.

10. The method as set forth in claim 9, wherein processing includes:
applying a first spectral fast Fourier transform;
performing automated phase correction to separate absorption mode and dispersion mode parts of the spectrum;
applying a second spectral fast Fourier transform to the separated parts; and
recombining the transformed parts to generate a pure absorption mode J-spectrum without a phase twist line shape.

11. The method as set forth in claim 1, further including:
processing the heteronuclear J-modulated data to extract both coupling and chemical shift information.

12. The method as set forth in claim 11, wherein the processing includes:
applying a plurality of transforms to the heteronuclear J-modulated data to generate a tilted two-dimensional J-spectrum having tilted axes corresponding to chemical shift and J-coupling components.

13. The method as set forth in claim 12, wherein the processing further includes:
rotating the tilted two-dimensional J-spectrum by 45° to generate an untilted two-dimensional J-spectrum having untilted axes corresponding to chemical shift and J-coupling components.

14. The method as set forth in claim 12, wherein the processing further includes:
applying an affine transformation to the tilted two-dimensional J-spectrum to generate an untilted two-dimensional J-spectrum having untilted axes corresponding to chemical shift and J-coupling components.

15. The method as set forth in claim 1, further including:
processing the heteronuclear J-modulated data to extract a two-dimensional J-spectrum; and
identifying chemical configurations between the first and second nuclear species in the two-dimensional J-spectrum based on matching the two-dimensional J-spectrum with a priori known J-spectra of selected chemical configurations.

16. The method as set forth in claim 15, wherein the first nuclear species is a carbon nucleus, the second nuclear species is a hydrogen nuclear species, and the two-dimensional J-spectrum is matched with a priori known J-spectra for at least —C, —CH, —CH₂, and —CH₃ chemical configurations.

17. The method as set forth in claim 1, further including:
applying magnetic field gradients to produce at least one of (i) spatial encoding and (ii) spatial localization of the generated heteronuclear J-modulated data;
processing the heteronuclear J-modulated data to extract at least one of (i) coupling information and (ii) chemical shift information; and
reconstructing an image from the generated heteronuclear J-modulated data.

18. The method as set forth in claim 1, further including:
prior to the exciting of the first nuclear species magnetic resonance, pre-saturating spins of the second nuclear species to obtain an Overhauser enhancement of the signal-to-noise ratio of the spin echo acquired by the reading.

19. A magnetic resonance apparatus comprising:
a magnetic resonance scanner; and
a controller controlling the magnetic resonance scanner to perform the magnetic resonance spectroscopy method set forth in claim 1.

20. A magnetic resonance apparatus comprising:
a means for acquiring heteronuclear J-modulated data; and
a processor for processing the acquired heteronuclear J-modulated data to extract at least one of (i) coupling information and (ii) chemical shift information.

21. A magnetic resonance spectroscopy method comprising:
acquiring first nuclear species magnetic resonance;
during the acquiring, spectrally encoding J-coupling of the first nuclear species with a second nuclear species by decoupling the second nuclear species over a decoupling time interval (Δ) during the acquiring;
repeating the acquiring with spectral encoding using a plurality of different decoupling time intervals (Δ) to generate heteronuclear J-modulated data containing both chemical shift and J-coupling information; and
processing the heteronuclear J-modulated data to extract at least one of the chemical shift information and the J-coupling information.

22. The magnetic resonance spectroscopy method as set forth in claim 21, wherein the processing includes:
reconstructing a J-spectrum having a chemical shift axis and an orthogonal J-coupling axis.

23. The magnetic resonance spectroscopy method as set forth in claim 21, wherein the decoupling time interval (Δ) of each repetition is substantially less than a readout time of the acquiring of that repetition.
